(19) United States
(12) Patent Application Publication
(10) Pub. No.: US 2025/0116780 A1
(43) Pub. Date: Apr. 10, 2025

(54) IMAGE SENSING DEVICE AND LIDAR DEVICE

(71) Applicants: Samsung Electronics Co., Ltd., Suwon-si (KR); SOGANG UNIVERSITY RESEARCH FOUNDATION, Seoul (KR)

(72) Inventors: Young KIM, Suwon-si (KR); Jinwook BURM, Seoul (KR); Seungju LEE, Seoul (KR); Jaehun JEONG, Seoul (KR); Jonghyuk CHAE, Seoul (KR)

(73) Assignees: Samsung Electronics Co., Ltd., Suwon-si (KR); SOGANG UNIVERSITY RESEARCH FOUNDATION, Seoul (KR)

(21) Appl. No.: 18/818,780

(22) Filed: Aug. 29, 2024

(30) Foreign Application Priority Data
Oct. 10, 2023 (KR) 10-2023-0134360

(51) Int. Cl. G01S 17/894; G01S 7/4863

(52) U.S. Cl. CPC G01S 17/894; G01S 7/4863

(57) ABSTRACT

An image sensing device and a light detection and ranging (LiDAR) device include a single-photon avalanche diode (SPAD) array including SPAD pixels, a signal transmission unit including row lines connected in units of SPAD pixels of a same row and column lines connected in units of SPAD pixels of a same column, a bias circuit unit outputting a row bias signal corresponding to a row photon signal transmitted through a row line of the signal transmission unit and outputting a column bias signal corresponding to a column photon signal transmitted through a column line of the signal transmission unit, a logic circuit unit identifying, based on the row bias signal and the column bias signal, a SPAD pixel that has detected a photon, and a counter array performing photon counting with respect to a counter that corresponds to the identified SPAD pixel among counters corresponding to the SPAD array.

### CROSS-REFERENCE TO RELATED APPLICATION

This application is based on and claims priority under 35 U.S.C. § 119 to Korean Patent Application No. 10-2023-0134360, filed on Oct. 10, 2023, in the Korean Intellectual Property Office, the disclosure of which is incorporated by reference herein in its entirety.

### BACKGROUND

### 1. Field

The inventive concepts relate to image sensing devices and light detection and ranging (LiDAR) devices.

### 2. Description of the Related Art

Light detection and ranging (LiDAR) systems are used in a variety of fields such as aerospace, geology, three-dimensional mapping, automobiles, robots, and drones. LIDAR devices have a function of measuring the distance between an imaging device and an object using, as an operational principle, a method of measuring the time that light needs to travel back and forth (hereinafter referred to as a time of flight (ToF) method). For example, a LiDAR device measures the ToF of light by emitting light toward an object, receiving, via a sensor, light reflected from the object, and performing a signal processing operation by using a circuit. Then, the LiDAR device may calculate the distance to the object using the ToF and may generate a depth image of the object by using calculated distances to positions of the object. In this manner, LiDAR devices may be used in various technical fields for various purposes. Recently, research has been conducted into techniques of generating two-dimensional images using a photo-counting imaging method in which the amount of light is measured in units of pixels by counting, by using fast photodiodes such as single-photon avalanche diodes (SPADs), the number of photons incident onto pixels for a particular (or, alternatively, predetermined) period of time.

### SUMMARY

Provided is an image sensing device and a light detection and ranging (LiDAR) device. Technical aspects of the inventive concepts are not limited to those mentioned above, and other technical aspects of the inventive concepts will be apparently understood through the following descriptions of some example embodiments.

Additional aspects will be set forth in part in the description which follows and, in part, will be apparent from the description, or may be learned by practice of the presented embodiments of the inventive concepts.

According to some example embodiments of the inventive concepts, an image sensing device includes a single-photon avalanche diode (SPAD) array including an m×n array of SPAD pixels, m and n each independently being a natural number, a signal transmission unit including m row lines connected in units of SPAD pixels of a same row of the SPAD array and n column lines connected in units of SPAD pixels of a same column of the SPAD array, a bias circuit unit configured to output a row bias signal corresponding to a row photon signal transmitted through a row line of the signal transmission unit and output a column bias signal corresponding to a column photon signal transmitted through a column line of the signal transmission unit, a logic circuit unit configured to identify, based on the row bias signal and the column bias signal, a SPAD pixel of the SPAD array that has detected a photon, and a counter array configured to perform photon counting with respect to a counter that corresponds to the identified SPAD pixel among an m×n array of counters corresponding to the m×n array of the SPAD array.

In addition, the signal transmission unit may be configured to provide the bias circuit unit with the row photon signal such that the row photon signal has a current intensity corresponding to a number of SPAD pixels that have detected photons among SPAD pixels connected to a same row line, and the column photon signal such that the column photon signal has a current intensity corresponding to a number of SPAD pixels that have detected photons among SPAD pixels connected to a same column line.

In addition, the bias circuit unit may include first current mirror circuits at separate, respective ends of the m row lines, and second current mirror circuits at separate, respective ends of the n column lines.

In addition, the logic circuit unit may include an m×n array of logic gates corresponding to the m×n array of the SPAD array, and each of the logic gates may include a first input terminal connected to one of the m row lines and a second input terminal connected to one of the n column lines.

In addition, the logic circuit unit may be further configured to identify, as the SPAD pixel that has detected the photon, a SPAD pixel corresponding to a logic gate to which the row bias signal is input through the first input terminal of the logic gate and to which the column bias signal is input through the second input terminal of the logic gate among the logic gates.

In addition, each of the logic gates may include a NOR gate circuit including the first input terminal and the second input terminal.

In addition, the counter array may be further configured to perform the photon counting with respect to the counter corresponding to the logic gate to which the row bias signal is input through the first input terminal of the logic gate and to which the column bias signal is input through the second input terminal of the logic gate among the logic gates.

In addition, the logic circuit unit may include logic gates connected to the SPAD pixels in a one-to-one manner, and the counter array may include counters connected to the logic gates in a one-to-one manner.

In addition, the image sensing device may further include a latency reducing circuit unit configured to receive a first row bias signal as an input to a first row inverter group, provide an output of the first row inverter group to a first input terminal of a first logic gate in the logic circuit unit, receive a first column bias signal as an input to a first column inverter group, and provide an output of the first column inverter group to a second input terminal of the first logic gate in the logic circuit unit.

In addition, the first row inverter group may include a first inverter and a second inverter and a first AND gate, wherein the first inverter and the second inverter and the first AND gate may be configured to receive the first row bias signal, perform an AND operation on inverted signals of the first row bias signal, and output a result of the AND operation to the first input terminal of the first logic gate, a strength of a p-channel metal-oxide-semiconductor (PMOS) transistor in the first inverter may be greater than a strength of an n-channel metal-oxide-semiconductor (NMOS) transistor in the first inverter, and a strength of a PMOS transistor in the second inverter may be identical to a strength of an NMOS transistor provided in the second inverter.

In addition, the first column inverter group may include a third inverter and a fourth inverter and a second AND gate, wherein the third inverter and the fourth inverter and the second AND gate may be configured to receive the first column bias signal, perform an AND operation on inverted signals of the first column bias signal, and output a result of the AND operation to the second input terminal of the first logic gate, and a strength of a PMOS transistor in the third inverter may be greater than a strength of an NMOS transistor in the third inverter, and a strength of a PMOS transistor in the fourth inverter is identical to a strength of an NMOS transistor in the fourth inverter.

According to another aspect of the inventive concepts, a light detection and ranging (LiDAR) device may include the image sensing device and a processor configured to generate, based on photon counting data received from the image sensing device, a digital image.

According to some example embodiments, a method may include transmitting, from a bias circuit unit, a row bias signal corresponding to a row photon signal transmitted through a row line connected to a single-photon avalanche diode (SPAD) pixel of a SPAD array, and a column bias signal corresponding to a column photon signal transmitted through a column line connected to the SPAD pixel. The method may include identifying, at a logic circuit unit, based on the row bias signal and the column bias signal, that the SPAD pixel has detected a photon, and performing photon counting with respect to a counter that corresponds to the SPAD pixel.

In addition, the row photon signal may have a current intensity corresponding to a number of SPAD pixels that have detected photons among SPAD pixels connected to a same row line, and the column photon signal may have a current intensity corresponding to a number of SPAD pixels that have detected photons among SPAD pixels connected to a same column line.

In addition, the logic circuit unit may include a logic gate corresponding to the SPAD pixel, and the logic gate may include a first input terminal connected to the row line, and a second input terminal connected to the column line.

The method may further include identifying, the SPAD pixel as having detecting the photon based on both the row bias signal being input through the first input terminal of the logic gate, and the column bias signal being input through the second input terminal of the logic gate.

The logic gate may include a NOR gate circuit comprising the first input terminal and the second input terminal.

The method may further include receiving the row bias signal as an input to a first row inverter group, providing an output of the first row inverter group to a first input terminal of a logic gate, receiving the column bias signal as an input to a first column inverter group, and providing an output of the first column inverter group to a second input terminal of the logic gate.

The first row inverter group may include a first inverter and a second inverter and a first AND gate, where a strength of a p-channel metal-oxide-semiconductor (PMOS) transistor in the first inverter is greater than a strength of an n-channel metal-oxide-semiconductor (NMOS) transistor in the first inverter, and a strength of a PMOS transistor in the second inverter is identical to a strength of an NMOS transistor provided in the second inverter. The method may include inverting the row bias signal at the first inverter and the second inverter, performing an AND operation on inverted signals of the row bias signal at the first AND gate, and outputting a result of the AND operation to the first input terminal of the logic gate. The first column inverter group may include a third inverter and a fourth inverter and a second AND gate, where a strength of a PMOS transistor in the third inverter is greater than a strength of an NMOS transistor in the third inverter, and a strength of a PMOS transistor in the fourth inverter is identical to a strength of an NMOS transistor in the fourth inverter. The method may include inverting the column bias signal at the third inverter and the fourth inverter, performing an AND operation on inverted signals of the column bias signal at the second AND gate, and outputting a result of the AND operation to the second input terminal of the logic gate.

The method may further include generating a digital image, based on the photon counting.

### BRIEF DESCRIPTION OF THE DRAWINGS

The above and other aspects, features, and advantages of certain embodiments of the inventive concepts will be more apparent from the following description taken in conjunction with the accompanying drawings, in which:

FIG. 1 is a view illustrating a light detection and ranging (LiDAR) device according to some example embodiments;

FIG. 2 is a view illustrating a direct time of flight (dToF) method that uses pulsed laser light according to distances to objects according to some example embodiments;

FIGS. 3 and 4 are views illustrating a hardware configuration and a circuit configuration of an image sensing device according to some example embodiments;

FIG. 5 is a view illustrating an SPAD array and a signal transmission unit of an image sensing device according to some example embodiments;

FIG. 6 is a view illustrating an SPAD array and a signal transmission unit of an image sensing device according to some example embodiments;

FIG. 7 is a view illustrating a row bias circuit unit provided in a bias circuit unit according to some example embodiments;

FIG. 8 is a view illustrating a column bias circuit unit provided in a bias circuit unit according to some example embodiments;

FIG. 9 is a view illustrating a logic circuit unit according to some example embodiments;

FIG. 10 is a view illustrating a counter array according to some example embodiments;

FIG. 11 is a view illustrating a hardware configuration of an image sensing device according to some example embodiments;

FIG. 12 is a view illustrating a latency reducing circuit unit shown in FIG. 11 according to some example embodiments;

FIGS. 13 and 14 are views illustrating how to output an input signal after increasing the rising rate and the falling rate of the input signal by using two inverters of an inverter group according to some example embodiments; and

FIG. 15 is a flowchart illustrating a method according to some example embodiments.

### DETAILED DESCRIPTION

Reference will now be made in detail to example embodiments, some of which are illustrated in the accompanying drawings, wherein like reference numerals refer to like elements throughout. In this regard, some example embodiments may have different forms and should not be construed as being limited to the descriptions set forth herein. Accordingly, some example embodiments are merely described below, by referring to the figures, to explain aspects.

The terms used in the inventive concepts are general terms currently widely used in the art in consideration of functions regarding some example embodiments, but the terms may vary according to the intention of those of ordinary skill in the art, precedents, or new technology in the art. Also, some terms may be arbitrarily selected by the applicant, and in this case, the meaning of the selected terms will be described in the detailed description of the inventive concepts. Thus, the terms used herein should not be construed based on only the names of the terms but should be construed based on the meaning of the terms together with the description throughout the inventive concepts.

In the following descriptions of some example embodiments, when a portion or element is referred to as being connected to another portion or element, the portion or element may be directly connected to the other portion or element, or may be electrically connected to the other portion or elements with intervening portions or elements being therebetween. The terms of a singular form may include plural forms unless otherwise mentioned. It will be further understood that the terms “comprises” and/or “comprising” used herein specify the presence of stated features or elements, but do not preclude the presence or addition of one or more other features or elements.

In the following descriptions of some example embodiments, expressions or terms such as “constituted by,” “formed by,” “include,” “comprise,” “including,” and “comprising” should not be construed as always including all specified elements, processes, or operations, but may be construed as not including some of the specified elements, processes, or operations, or further including other elements, processes, or operations.

In addition, although the terms “first” and “second” are used to describe various elements, these elements should not be limited by these terms. These terms are only used to distinguish one element from other elements.

The following descriptions of some example embodiments should not be construed as limiting the scope of the inventive concepts, and modifications or changes that could be easily made from some example embodiments by those of ordinary skill in the art should be construed as being included in the scope of the inventive concepts. Hereinafter, some example embodiments will be described with reference to the accompanying drawings.

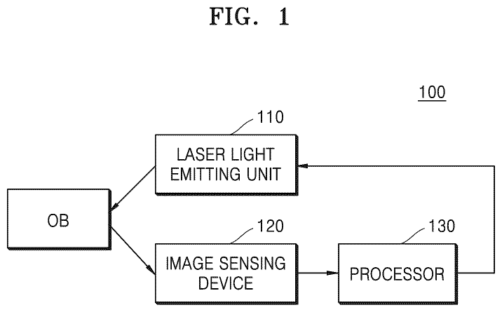

FIG. 1 is a view illustrating a light detection and ranging (LiDAR) device 100 according to some example embodiments.

Referring to FIG. 1, the LiDAR device 100 may be used as a sensor for acquiring three-dimensional information such as distance information about a front object in real time. For example, the LiDAR device 100 may be applied to unmanned vehicles, autonomous vehicles, robots, drones, or the like. For example, the LiDAR device 100 may be a device employing a LiDAR technique.

The LiDAR device 100 may include a laser light emitting unit 110, an image sensing device 120, and a processor 130. Although FIG. 1 illustrates only components of the LiDAR device 100 that are related to some example embodiments, the example embodiments are not limited thereto. Those of ordinary skill in the art will understand that the LiDAR device 100 may further include other general-purpose components in addition to the components shown in FIG. 1.

The laser light emitting unit 110 may emit pulsed laser light toward an object OB to analyze the position and shape of the object OB, and the distance to the object OB. That is, the laser light emitting unit 110 may generate and emit pulsed light.

The laser light emitting unit 110 may emit light using a laser light source, but is not limited thereto. The laser light emitting unit 110 may use a light source such as an edge emitting laser, a vertical-cavity surface emitting laser (VCSEL), a distributed feedback laser, or a super luminescent diode (SLD). For example, the laser light emitting unit 110 may include a laser diode (LD). In some embodiments, the laser light emitting unit 110 may be included in another device and may not be implemented by hardware included in the LiDAR device 100.

The laser light emitting unit 110 may set the emission direction or angle of light under control by the processor 130. Although not shown in FIG. 1, the laser light emitting unit 110 may further include a beam steering device to vary the emission angle of light. The beam steering device may be a scanning mirror, an optical phased array, or the like.

The image sensing device 120 may output an electrical signal by detecting pulsed laser light (pulsed light) reflected or scattered from the object OB. For example, the image sensing device 120 may output photon counting data based on light reflected or scattered from the object OB.

The image sensing device 120 may include a light receiving device such as a sensor capable of sensing reflected pulsed laser light. For example, the image sensing device 120 may include a single-photon avalanche diode (SPAD) or an avalanche photo diode (APD). That is, the image sensing device 120 may detect a reflected pulsed laser light signal by receiving pulsed laser light reflected from the object OB using a light receiving device such as an SPAD.

The SPAD refers to a next-generation optical semiconductor device having a very high efficiency and capable of detecting even a single photon owing to a very high gain thereof. When a voltage higher than the breakdown voltage of the SPAD is applied to the SPAD, free electrons (carriers) are accelerated and strongly collided with atoms by a very intensive electric field, thereby releasing electrons bound to the atoms and rapidly increasing the number of free electrons. That is, impact ionization occurs. This is called avalanche multiplication, and owing to this effect, the number of free electrons generated by photons emitted from the outside to an image sensor may markedly increase. In other words, even when only a very small number of photons enter an image sensor in a very dark environment or an environment in which light comes from a very distant location, the image sensor may multiply the photons and recognize as if many photons enter the image sensor.

In an imaging process using a photon counting technique, a two-dimensional image may be generated by counting the number of photons incident on each pixel for a certain period of time along a time axis, and measuring the amount of light in units of pixels. Therefore, the image sensing device 120 may refer to a hardware device configured to detect pulsed light and perform photon counting.

The processor 130 may control all operations of various hardware/software components of the LiDAR device 100.

The processor 130 may calculate the distance to the object OB based on a time of flight (ToF) method and may perform data processing to analyze the location and shape of the object OB. For example, the processor 130 may generate a depth image of the object OB using a distance calculated based on photon counting.

Information on (associated with) the shape and location of the object OB analyzed by the processor 130 may be transmitted to and utilized by another unit. For example, such information may be transmitted to a self-driving apparatus such as a self-driving vehicle or a drone that employs the LiDAR device 100. In addition, such information may also be transmitted to a computing device such as a smartphone, a tablet, a laptop computer, a personal computer (PC), or a wearable device.

The LiDAR device 100 may further include memory in which programs and other data for operations of the processor 130 are stored. The memory may be hardware that stores various pieces of data processed within the LiDAR device 100. For example, the memory may store data processed by the LiDAR device 100 and data to be processed by the LiDAR device 100. In addition, the memory may store software such as applications or drivers to be executed by the LiDAR device 100. The memory may include random access memory (RAM) such as dynamic random access memory (DRAM) or static random access memory (SRAM), read-only memory (ROM), electrically erasable programmable read-only memory (EEPROM), an optical disc storage such as CD-ROM or Blu-ray, a hard disk drive (HDD), a solid state drive (SSD), or flash memory. Furthermore, the memory may include an external storage device that is accessible by the LiDAR device 100.

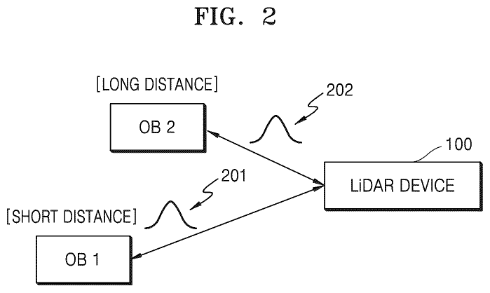

FIG. 2 is a view illustrating a direct ToF (dToF) method that uses pulsed laser light according to the distances to objects according to some example embodiments.

Referring to FIG. 2, the LiDAR device 100 may measure the distance to an object OB1 located at a long distance or the distance to an object OB2 located at a short distance by using laser light.

For example, the LiDAR device 100 may calculate the distance to the object OB1 located at a long distance based on a ToF from the moment of emitting pulsed laser light toward the object OB1 to the moment of detecting a laser light reflection signal 201 reflected from the object OB1. Likewise, the LiDAR device 100 may calculate the distance to the object OB2 located at a short distance based on a ToF from the moment of emitting pulsed laser light toward the object OB2 to the moment of detecting a laser light reflection signal 202 reflected from the object OB2. That is, the LiDAR device 100 may be a device configured to calculate distances by a dToF method. However, the LiDAR device 100 is not limited thereto.

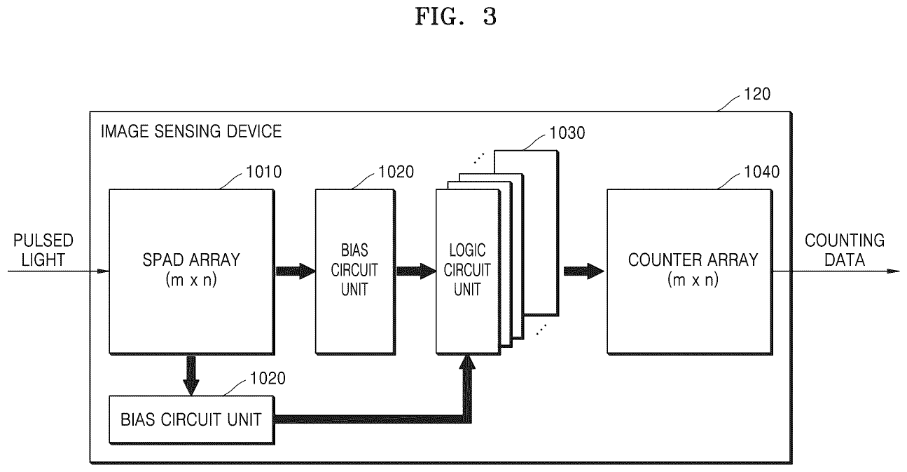

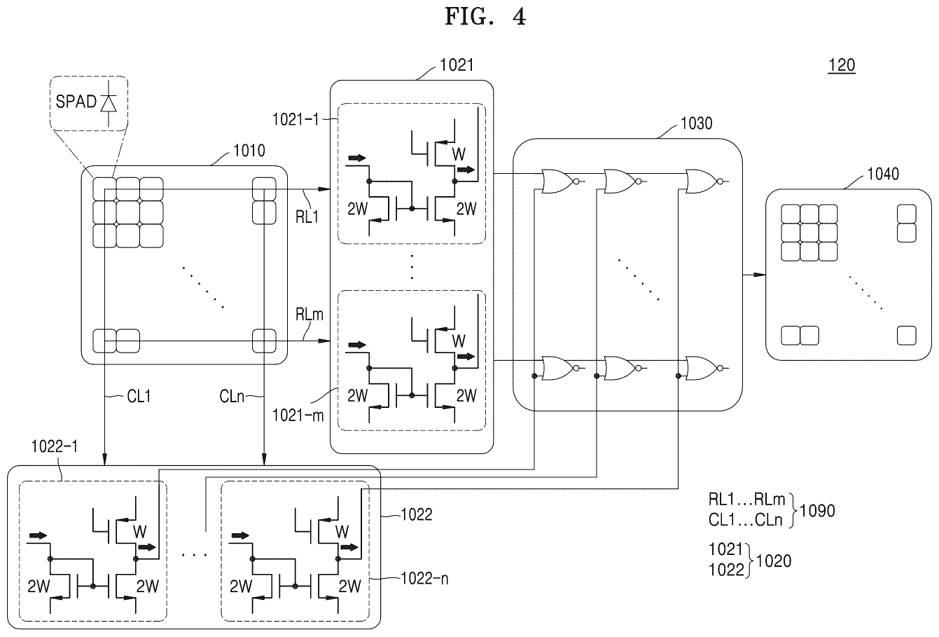

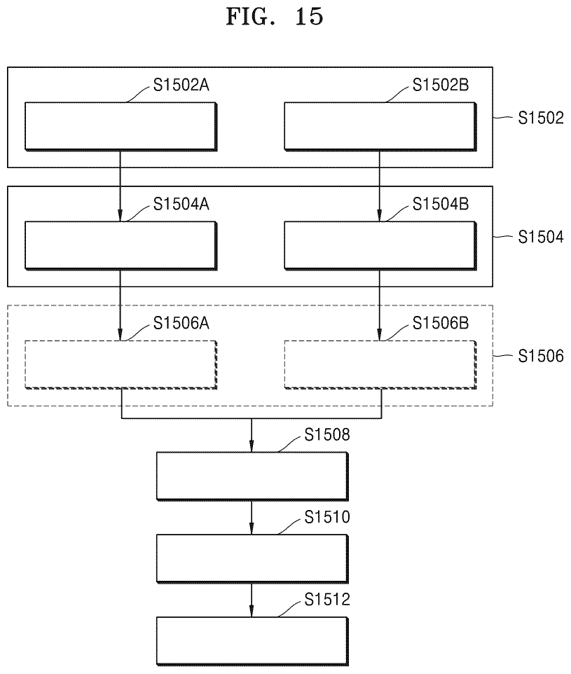

FIGS. 3 and 4 are views illustrating a hardware configuration and a circuit configuration of the image sensing device 120 according to some example embodiments. FIG. 15 is a flowchart illustrating a method according to some example embodiments. The method shown in FIG. 15 may be performed by one or more example embodiments of an image sensing device, LiDAR device, or the like as described herein.

Referring to FIGS. 3 and 4, the image sensing device 120 may include a SPAD array 1010, a bias circuit unit 1020, a logic circuit unit 1030, and a counter array 1040. Although FIGS. 3 and 4 illustrate only components of the image sensing device 120 according to some example embodiments, the example embodiments are not limited thereto. Those of ordinary skill in the art will understand that the image sensing device 120 may further include other general-purpose components in addition to the components shown in FIGS. 3 and 4.

The SPAD array 1010 may include an m×n array of SPAD pixels (m and n refer to natural numbers, where m and n may each independently be a natural number). Each of the SPAD pixels corresponds to a pixel implemented as an SPAD device for detecting a single photon from pulsed laser light reflected or scattered from an object OB.

The image sensing device 120 may include a signal transmission unit 1090. In the SPAD array 1010, a signal transmission unit 1090 refers to m row lines RL connected in units of SPAD pixels of the same row of the SPAD array 1010 and n column lines CL connected in units of SPAD pixels of the same column of the SPAD array 1010. Referring to FIGS. 3 and 4 and 15, the signal transmission unit 1090 may, at S1502, provide the bias circuit unit 1020 with a row photon signal (S1502A) having a current intensity corresponding to the number (quantity) of SPAD pixels that have detected photons among SPAD pixels connected to the same row line RL, and a column photon signal (S1502B) having a current intensity corresponding to the number of SPAD pixels that have detected photons among SPAD pixels connected to the same column line CL.

Referring to FIGS. 3 and 4 and 15, the bias circuit unit 1020 may, at S1504, output (transmit) a row bias signal RBS corresponding to a row photon signal transmitted through a row line RL of the signal transmission unit 1090 (S1504A) and may output (transmit) a column bias signal CBS corresponding to a column photon signal transmitted through a column line CL of the signal transmission unit 1090 (S1504B), where the row line RL and the column line CL may be connected to the same SPAD pixel of the SPAD array 1010. The bias circuit unit 1020 may include: current mirror circuits respectively provided at ends of the m row lines RL; and current mirror circuits respectively provided at ends of the n column lines CL. Each of the current mirror circuits may be a circuit implemented for, at S1504, biasing the intensity of input current and outputting a current having the same intensity as the intensity of the input current or a current having an intensity proportional to the intensity of the input current (that is, outputting a row bias signal or a column bias signal). In some example embodiments, each of the current mirror circuits may be a circuit implemented for performing an inverting operation such that when a current having a particular (or, alternatively, predetermined) intensity is input, the circuit may output a current having an intensity indicating a low signal (that is, a row bias signal or a column bias signal).

The bias circuit unit 1020 may include: a row bias circuit unit 1021 configured to bias a row bias signal RBS corresponding to a row photon signal transmitted through a row line RL of the signal transmission unit; and a column bias circuit unit 1022 configured to bias a column bias signal CBS corresponding to a column photon signal transmitted through a column line CL of the signal transmission unit. The row bias circuit unit 1021 may include m current mirror circuits 1021-1 to 1021-m (referred to as first current mirror circuits) corresponding to the m×n array of SPAD pixels. The m current mirror circuits 1021-1 to 1021-m may be at (e.g., may be connected to) separate, respective ends of the m row lines, for example such that current mirror circuit 1021-1 may be connected to an end of row line RL 1 and current mirror circuit 1021-m may be connected to an end of row line RL m. In addition, the column bias circuit unit 1022 may include n current mirror circuits 1022-1 to 1022-n (referred to as second current mirror circuits) corresponding to the m×n array of SPAD pixels. The n current mirror circuits 1022-1 to 1022-n may be at (e.g., may be connected to) separate, respective ends of the n column lines, for example such that current mirror circuit 1022-1 may be connected to an end of column line CL 1 and current mirror circuit 1022-n may be connected to an end of column line CL n.

Referring to FIGS. 3 and 4 and 15, based on a row bias signal and a column bias signal (e.g., transmitted at S1504A and S1504B, respectively), the logic circuit unit 1030 may, at S1508, identify an SPAD pixel that has detected a photon, where such a SPAD pixel may be referred to herein as an identified SPAD pixel.

The logic circuit unit 1030 may include an m×n array of logic gates corresponding to the m×n array of the SPAD array 1010. Here, to perform a logic operation, a first input terminal of each of the logic gates may be connected to any one of the m row lines RL, and a second input terminal of each of the logic gates may be connected to any one of the n column lines CL.

When a logic gate among the logic gates receives a row bias signal through the first input terminal of the logic gate and a column bias signal through the second input terminal of the logic gate, the logic circuit unit 1030 may, in response at S1508, identify an SPAD pixel corresponding to the logic gate as a SPAD pixel in which a photon is detected (e.g., an identified SPAD pixel). The logic gates may be implemented as NOR gates, but are not limited thereto. The logic gates may be implemented as other types of gate circuits.

The counter array 1040 may include an m×n array of counters corresponding to the m×n array of the SPAD array 1010. Referring to FIGS. 3 and 4 and 15, among the m×n array of counters, a counter corresponding to an SPAD pixel identified by the logic circuit unit 1030 (e.g., identified at S1508) may perform photon counting (S1510). Photon counting data generated by the counter array 1040 may be provided to the processor 130 (e.g., as part of S1510).

The logic circuit unit 1030 may include logic gates connected to the SPAD pixels of the SPAD array 1010 in a one-to-one manner, and the counter array 1040 may include counters connected to the logic gates in a one-to-one manner.

As the resolution of the SPAD array 1010 increases, image quality may increase, and more accurate information on an object OB (e.g., an object in an image) may be obtained. However, as the resolution of the SPAD array 1010 increases, the complexity of circuits provided around the SPAD array 1010 may increase. Thus, it may be difficult to increase only the resolution of the SPAD array 1010 in a limited device space.

For example, assuming that different 16×16 data lines are connected to pixels of a 16×16 pixel array, it may be difficult to implement more pixels due to the number of data lines. In other words, there are limitations in reducing the size of one pixel within an area of a given size. The width of lines may be reduced to arrange an increased number of lines within a given pixel size. However, this method also has limitations.

The image sensing device 120 of some example embodiments may be related to methods of efficiently implementing the SPAD array 1010 and peripheral circuits of the SPAD array 1010.

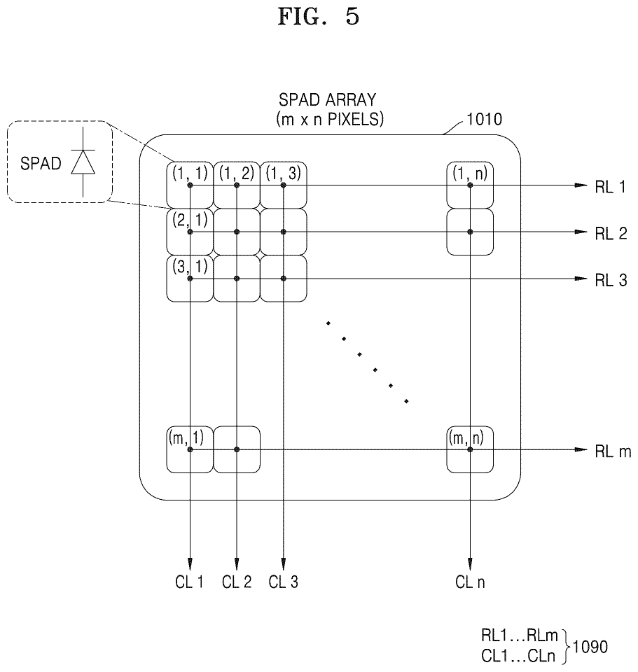

FIG. 5 is a view illustrating the SPAD array 1010 and the signal transmission unit of the image sensing device 120 according to some example embodiments.

Referring to FIG. 5, the SPAD array 1010 includes an m×n array of SPAD pixels (m and n refer to natural numbers). For ease of description, the SPAD pixels are denoted with (1,1) to (m,n) depending on the positions thereof.

n SPAD pixels (1,1) to (1,n) arranged in a first row may be connected to the same row line RL 1. Likewise, n SPAD pixels arranged in the same row may be connected to the same row line RL. The signal transmission unit 1090 may include m row lines RL 1 to RL m.

m SPAD pixels (1,1) to (m,1) arranged in a first column may be connected to the same column line CL 1. Likewise, m SPAD pixels arranged in the same column may be connected to the same column line CL. The signal transmission unit 1090 may include n column lines CL 1 to CL n.

Each row line RL is shared by SPAD pixels arranged in the same row and transmits a photon signal, and each column line CL is shared by SPAD pixels arranged in the same column and transmits a photon signal. In other words, one row line RL and one column line CL may be connected to one SPAD pixel, and thus, when a photon is detected in a SPAD pixel, a photon signal may be transmitted to and through a row line RL and a column line CL connected to the SPAD pixel.

Because the row lines RL and the column lines CL are shared by and connected to the SPAD pixels, a more efficient circuit configuration may be possible than in the related art in which different lines are connected to each pixel. As a result, an image sensing device 120 where the row lines RL and the column lines CL are shared by and connected to the SPAD pixels of the SPAD array 1010, a complexity of circuits provided around the SPAD array 1010 may be reduced or minimized. Thus, the image sensing device 120 may be configured to provide increased resolution of the SPAD array 1010 in a limited device space. Accordingly, the image sensing device 120 may have improved compactness or miniaturization, may be configured to provide improved image sensing performance in a limited device space, and/or may be configured to provide a SPAD array 1010 in a limited device space without compromising resolution of the SPAD array 1010. Accordingly, the image sensing performance provided by the image sensing device 120 in a compact space may be improved, and thus compactness of the image sensing device 120 and any device including same (e.g., LiDAR device 100). Additionally, due to the more efficient circuit configuration of the image sensing device 120 provided based on the row lines RL and the column lines CL being shared by and connected to the SPAD pixels, the reliability of the image sensing device 120 and any device including same (e.g., LIDAR device 100) may be improved due to reduced complexity of the circuit configuration associated with the SPAD array 1010. Furthermore, due to the more efficient circuit configuration of the image sensing device 120 provided based on the row lines RL and the column lines CL being shared by and connected to the SPAD pixels, the cost and complexity of processes to manufacture the image sensing device 120 may be reduced, thereby both reducing per-unit costs of the image sensing device 120 and any device (e.g., LiDAR device 100) including same and further improving reliability of the image sensing device 120 and any device including same due to reduced likelihood of process defects due to reduced complexity of the manufacturing process.

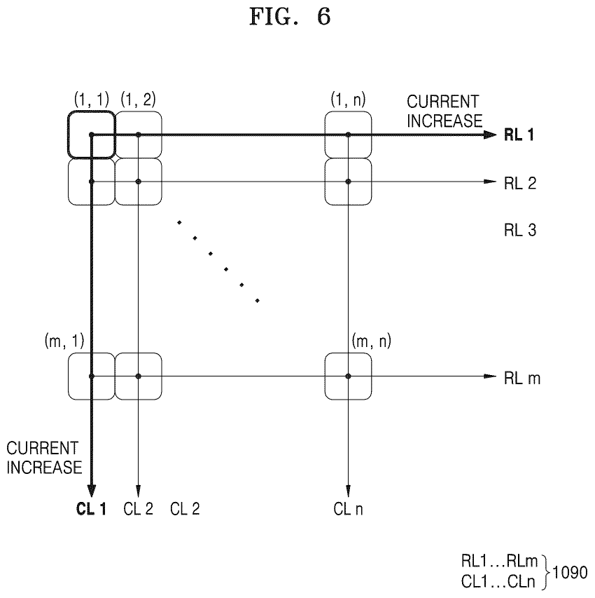

FIG. 6 is a view illustrating the SPAD array 1010 and the signal transmission unit 1090 of the image sensing device 120 according to some example embodiments.

FIG. 6 illustrates an example in which a photon is detected at the SPAD pixel (1,1) of the m×n array of the SPAD array 1010. When pulsed light is incident on the SPAD pixel (1,1), the number (quantity) of free electrons rapidly increases in a SPAD device of the SPAD pixel (1,1) by avalanche multiplication, resulting in an increase in current. Therefore, increased current flows through the row line RL 1 and the column line CL 1 connected to the SPAD pixel (1,1).

FIG. 6 illustrates an example that is related to only one SPAD pixel. However, when pulsed light is incident on any one of m×n SPAD pixels, current may increase as described above, and thus, a current may flow through a corresponding row line RL and a corresponding column line CL. That is, row photon signals and column photon signals may be transmitted through the row lines RL 1 to RL m and the column lines CL 1 to CL n connected to the SPAD array 1010.

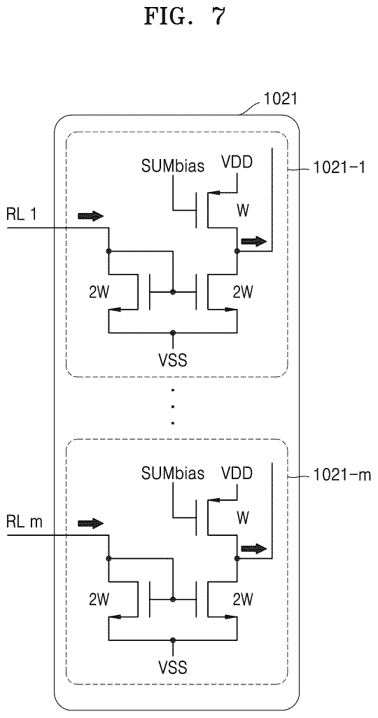

FIG. 7 is a view illustrating the row bias circuit unit 1021 provided in the bias circuit unit 1020 according to some example embodiments.

Referring to FIG. 7, the row bias circuit unit 1021 may include a plurality of current mirror circuits 1021-1 to 1021-m. That is, the current mirror circuits 1021-1 to 1021-m may be respectively connected to ends of the m row lines RL 1 to RL m, corresponding to the m×n array of the SPAD array 1010.

The row bias circuit unit 1021 uses each of the current mirror circuits 1021-1 to 1021-m to output (transmit) a row bias signal RBS corresponding to a row photon signal transmitted through a row line RL For example, each of the current mirror circuits 1021-1 to 1021-m may be a circuit implemented for biasing the intensity of input current and outputting a current having the same intensity as the intensity of the input current or a current having an intensity proportional to the intensity of the input current (that is, outputting a row bias signal). In some example embodiments, each of the current mirror circuits 1021-1 to 1021-m may be a circuit implemented for performing an inverting operation such that when a current having a particular (or, alternatively, predetermined) intensity is input, the circuit may output a current having an intensity indicating a low signal (that is, a row bias signal). In other words, the current mirror circuits 1021-1 to 1021-m are not limited to any one method and may be implemented in various manners.

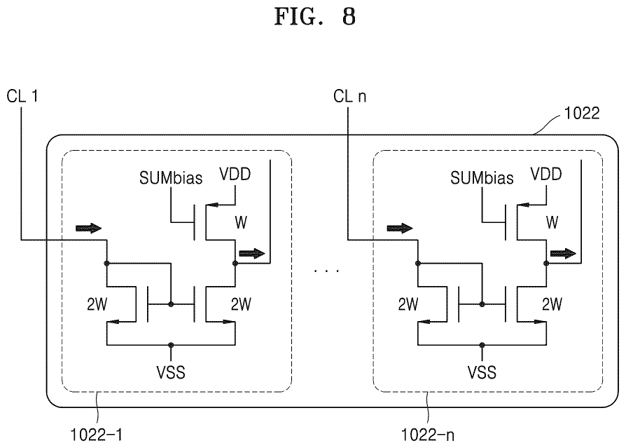

FIG. 8 is a view illustrating the column bias circuit unit 1022 provided in the bias circuit unit 1020 according to some example embodiments.

Referring to FIG. 8, the column bias circuit unit 1022 may include a plurality of current mirror circuits 1022-1 to 1022-n. That is, the current mirror circuits 1022-1 to 1022-n may be respectively connected to ends of the n column lines CL 1 to CL n, corresponding to the m×n array of the SPAD array 1010.

The column bias circuit unit 1022 uses each of the current mirror circuits 1022-1 to 1022-n to output (transmit) a column bias signal CBS corresponding to a column photon signal transmitted through a column line CL. For example, each of the current mirror circuits 1022-1 to 1022-n may be a circuit implemented for biasing the intensity of input current and outputting a current having the same intensity as the intensity of the input current or a current having an intensity proportional to the intensity of the input current (that is, outputting a column row bias signal). In some example embodiments, each of the current mirror circuits 1022-1 to 1022-n may be a circuit implemented for performing an inverting operation such that when a current having a particular (or, alternatively, predetermined) intensity is input, the circuit may output a current having an intensity indicating a low signal (that is, a column bias signal). In other words, the current mirror circuits 1022-1 to 1022-n are not limited to any one method and may be implemented in various manners.

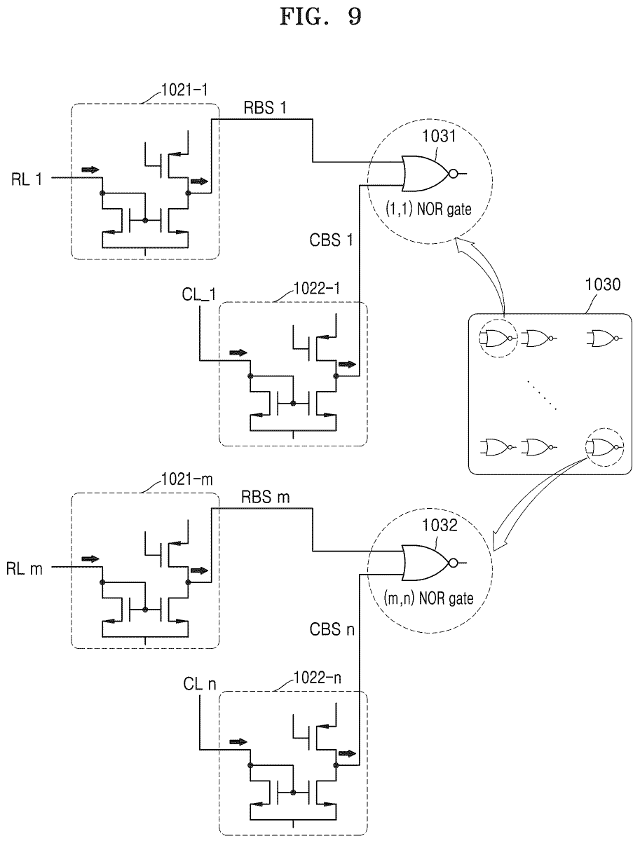

FIG. 9 is a view illustrating the logic circuit unit 1030 according to some example embodiments.

Referring to FIG. 9, the logic circuit unit 1030 may include m×n logic gates connected to the m×n SPAD pixels of the SPAD array 1010 in a one-to-one manner, for example such that each logic gate may correspond to a separate one of the m×n SPAD pixels and may be configured to receive signals at the first and second input terminals thereof based on one or more photon signals generated by the separate one SPAD pixel. Each of the logic gates may include: a first input terminal connected to an output end of one of the m current mirror circuits 1021-1 to 1021-m of the row bias circuit unit 1021 to receive a row bias signal RBS (and thus connected, indirectly, to one of the m row lines); and a second input terminal connected to an output end of one of the n current mirror circuits 1022-1 to 1022-n of the column bias circuit unit 1022 to receive a column bias signal CBS (and thus connected, indirectly, to one of the n column lines). Each of the logic gates may perform a logic operation between the first input terminal (a row bias signal RBS) and the second input terminal (a column bias signal CBS).

Each of the logic gates may be implemented as a NOR gate including a first input terminal and a second input terminal. For example, in the logic circuit unit 1030, a NOR gate 1031 corresponding to a position (1,1) may include: a first input terminal connected to an output RBS 1 of the current mirror circuit 1021-1 of the row bias circuit unit 1021; and a second input terminal connected to an output CBS 1 of the current mirror circuit 1022-1 of the column bias circuit unit 1022. Likewise, a NOR gate 1032 corresponding to a position (m,n) may include: a first input terminal connected to an output RBS m of the current mirror circuit 1021-m of the row bias circuit unit 1021; and a second input terminal connected to an output CBS n of the current mirror circuit 1022-n of the column bias circuit unit 1022.

Each of the logic gates of the logic circuit unit 1030, at S1508 of FIG. 15, performs a logic operation to identify a case in which photon signals are transmitted through both a row and a column. For example, when a logic gate is implemented as a NOR gate, a row bias signal RBS corresponding to a low signal may be input to the first input terminal of the logic gate (NOR gate), and a column bias signal CBS corresponding to the low signal may be input to the second input terminal of the logic gate (NOR gate). In this case, the logic gate (NOR gate) may output a high signal. The case in which a logic gate (NOR gate) outputs a high signal may indicate that a photon is detected by a SPAD pixel connected to both a row current mirror circuit and a column current mirror circuit that provide a row bias signal RBS and a column bias signal CBS. That is, in the SPAD array 1010, a SPAD pixel corresponding to the position of a logic gate (NOR gate) outputting a high signal may be a SPAD pixel that has detected a photon (e.g., an identified SPAD pixel).

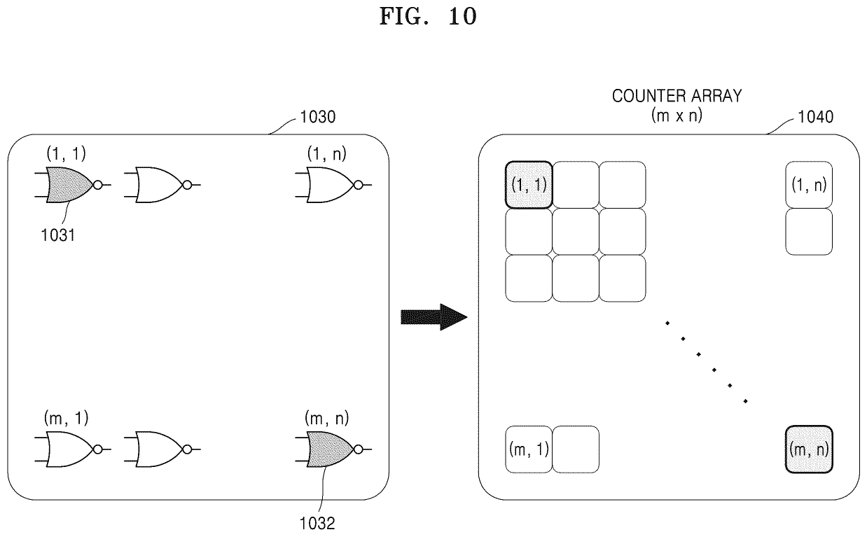

FIG. 10 is a view illustrating the counter array 1040 according to some example embodiments.

Referring to FIG. 10, the counter array 1040 may include an m×n array of counters connected to the m×n logic gates of the logic circuit unit 1030 in a one-to-one manner.

Each of the counters may, at S1510 of FIG. 15, count the number (quantity) of pulse signals and output (transmit) a counting value. Here, pulse signals that are input to the counters may correspond to high signals provided from the logic gates (NOR gates). That is, photon counting is performed in a counter corresponding to a logic gate (NOR gate) to which bias signals are input through both the first and second input terminals of the logic gate (e.g., row bias signals input through the first input terminal and column bias signals input through the second input terminal). In other words, when a high signal is output from a logic gate (NOR gate) corresponding to a SPAD pixel that has detected a photon, a counter corresponding to the logic gate increases (e.g., increments) a counting value.

A counting value of a counter at a certain position may refer to a pixel value of a SPAD pixel at a position corresponding to the certain position. Therefore, the counting value may refer to the total number of photons input for a frame period.

For example, when a logic gate (NOR gate) located at a position (1,1) of the logic circuit unit 1030 outputs a high signal, a counter located at a corresponding position (1,1) may perform counting by increasing a counting value in response to the high signal received from the logic gate. Likewise, when a logic gate (NOR gate) located at a position (m,n) of the logic circuit unit 1030 outputs a high signal, a counter located at a corresponding position (m,n) may perform counting by increasing a counting value in response to the high signal received from the logic gate.

Each of the counters of the counter array 1040 may have a certain number of bits, for example, 8 bits to 12 bits. The size of each of the counters is not limited thereto, and the counters may have various sizes depending on the pixel size of the SPAD array 1010 or applications of the image sensing device 120. The counters may be synchronous counters, asynchronous counters, or asynchronous ripple counters. The counters may include D-flip-flop circuits.

Referring to FIG. 15, photon counting data obtained using the counters of the counter array 1040 (e.g., based on performing the photon counting at S1510) may be provided to the processor 130, and the processor 130 may, at S1512, perform imaging using the photon counting data (that is, pixel values) of the SPAD array 1010 to generate an image (e.g., a digital image), for example where the image includes pixels corresponding to the SPAD pixels of the SPAD array 1010 and each pixel has a respective pixel value corresponding to the photon counting data corresponding to the corresponding SPAD pixel of the SPAD array 1010.

As described above, in the image sensing device 120 of some example embodiments, the SPAD array 1010 and peripheral circuit components (the bias circuit unit 1020, the logic circuit unit 1030, the counter array 1040, and the like) are efficiently arranged/connected to each other. Thus, the image sensing device 120 may be applied to various methods such as a back side illumination (BSI) method in which a layer for an SPAD array and a layer for a readout integrated circuit (IC) are different from each other.

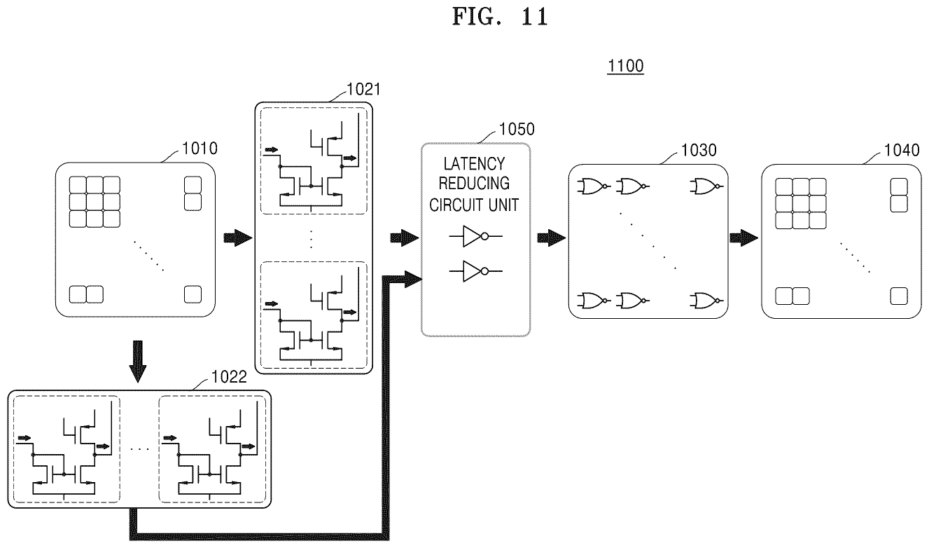

FIG. 11 is a view illustrating a hardware configuration of an image sensing device 1100 according to some example embodiments.

Unlike the image sensing device 120 described with reference to FIGS. 3 and 4, the image sensing device 1100 shown in FIG. 11 may further include a latency reducing circuit unit 1050. However, a SPAD array 1010, a bias circuit unit 1020, a logic circuit unit 1030, and a counter array 1040 of the image sensing device 1100 may be implemented as described above with reference to the accompanying drawings. Accordingly, referring to FIG. 15, the method shown therein may include an additional operation S1506 of the latency reducing circuit unit 1050 that may be absent in some example embodiments, such that in some example embodiments operation S1504 proceeds directly to S1508 without performing S1506.

The latency reducing circuit unit 1050 may be provided to reduce a dead time or latency that may occur during a low-to-high transition or a high-to-low transition of a pulsed signal.

The latency reducing circuit unit 1050 may be implemented as an inverter circuit to convert analog signals into digital signals. Here, when a single inverter is used, it is inevitable that the rate of rising or falling is defined by a strength ratio between an n-channel metal-oxide-semiconductor (NMOS) transistor and a p-channel metal-oxide-semiconductor (PMOS) transistor. Rising refers to a low-to-high transition of a signal, and falling refers to a high-to-low transition of a signal. In this case, a method of greatly increasing the size of the single inverter to increase the speed of the single inverter for both rising and falling may be considered. However, this method causes very large power consumption and may thus be not practicable.

Therefore, the latency reducing circuit unit 1050 may include inverter groups each including two inverters. For example, in each of the inverter groups, one inverter may include a PMOS transistor and an NMOS transistor that have different sizes to speed up rising, and the other inverter may include a PMOS transistor and an NMOS transistor that have the same size to speed up falling. In this manner, a dead time or latency may be reduced by adjusting the rate of rising or falling using the inverter groups provided in the latency reducing circuit unit 1050, thereby improving the image sensing performance of an image sensing device 1100 including the latency reducing circuit unit 1050. Additionally, the latency reducing circuit unit 1050 may enable improved power consumption efficiency of the image sensing device 1100 based on adjusting the rate of the aforementioned rising and/or falling of a signal without requiring additional excessive power consumption.

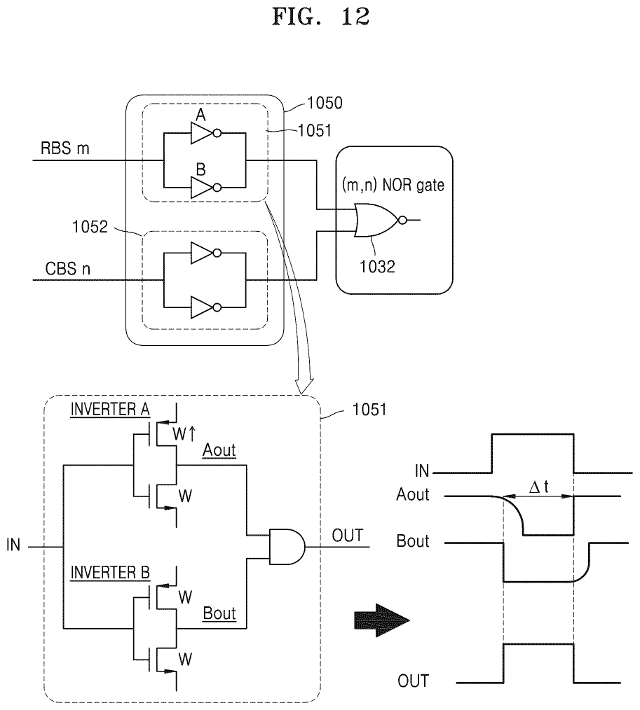

FIG. 12 is a view illustrating the latency reducing circuit unit 1050 shown in FIG. 11 according to some example embodiments.

Referring to FIG. 12, the latency reducing circuit unit 1050 may include a plurality of row inverter groups (for example, m row inverter groups) and a plurality of column inverter groups (for example, n column inverter groups). That is, the row inverter groups may be respectively provided for outputs of the current mirror circuits connected to the row lines RL, and the column inverter groups may be respectively provided for outputs of the current mirror circuits connected to the column lines CL.

For example, the latency reducing circuit unit 1050 may include: a row inverter group 1051 that receives a row bias signal RBS m of the current mirror circuit 1021-m connected to an mth row line RL m; and a column inverter group 1052 that receives a column bias signal CBS n of the current mirror circuit 1022-n connected to an nth column line CL n.

The row inverter group 1051 may, at S1506A of operation S1506 in FIG. 15, receive the row bias signal RBS m as an input, and an output of the row inverter group 1051 may be provided to the first input terminal of the logic gate (NOR gate) (m,n) of the logic circuit unit 1030.

The column inverter group 1052 may, at S1506B of operation S1506 in FIG. 15, receive the column bias signal CBS n as an input, and an output of the column inverter group 1052 may be provided to the second input terminal of the logic gate (NOR gate) (m,n) of the logic circuit unit 1030.

The row inverter group 1051 may include two inverters (inverters A and B), e.g., a first inverter and a second inverter, and an AND gate (e.g., a first AND gate). At S1506A, the inverters A and B receive the row bias signal RBS m and output an inverted signal of the row bias signal RBS m to the AND gate, and a result of a logic operation of the AND gate is output to the first input terminal of the logic gate (NOR gate) (m,n).

As shown in FIG. 12, each of the inverters A and B may be implemented as a circuit in which a PMOS transistor and an NMOS transistor are connected to each other.

The strength of the PMOS transistor provided in the inverter A may be greater than the strength of the NMOS transistor provided in the inverter A. However, the strength of the PMOS transistor provided in the inverter B may be the same as (identical to) the strength of the NMOS transistor provided in the inverter B.

Referring to a timing diagram shown in FIG. 12, it is shown that when a high signal IN is input to each of the inverters A and B of the row inverter group 1051, the falling rate of an output Aout of the inverter A is low, but the falling rate of an output Bout of the inverter B is high. Conversely, the rising rate of the output Aout of the inverter A is high, but the rising rate of the output Bout of the inverter B is low. Therefore, when the AND gate performs a logic operation on the outputs Aout and Bout of the inverters A and B, it is possible to obtain an output signal OUT by reducing a dead time or latency of the high signal IN input to the row inverter group 1051.

In addition, the column inverter group 1052 may also include two inverters (e.g., a third inverter and a fourth inverter) and an AND gate (e.g., a second AND gate). At S1506B, the inverters of the column inverter group 1052 receive a column bias signal CBS n and output an inverted signal of the column bias signal CBS n to the AND gate, and a result of a logic operation of the AND gate is output to the second input terminal of the logic gate (NOR gate) (m,n). As described above, the strength of the PMOS transistor provided in any one of the inverters of the column inverter group 1052 may be greater than the strength of the NMOS transistor provided in the same inverter. However, the strength of the PMOS transistor provided in the other inverter may be the same as the strength of the NMOS transistor provided in the other inverter.

That is, in each of the inverter groups, one inverter may include a PMOS transistor and an NMOS transistor that have different sizes to speed up rising, and the other inverter may include a PMOS transistor and an NMOS transistor that have the same size to speed up falling, thereby reducing a dead time or latency with respect to a signal input to the inverter group, and thus improving the image sensing performance of an image sensing device 1100 including the latency reducing circuit unit 1050. Additionally, the latency reducing circuit unit 1050 may enable improved power consumption efficiency based on adjusting the rate of the aforementioned rising and/or falling of a signal without requiring additional excessive power consumption.

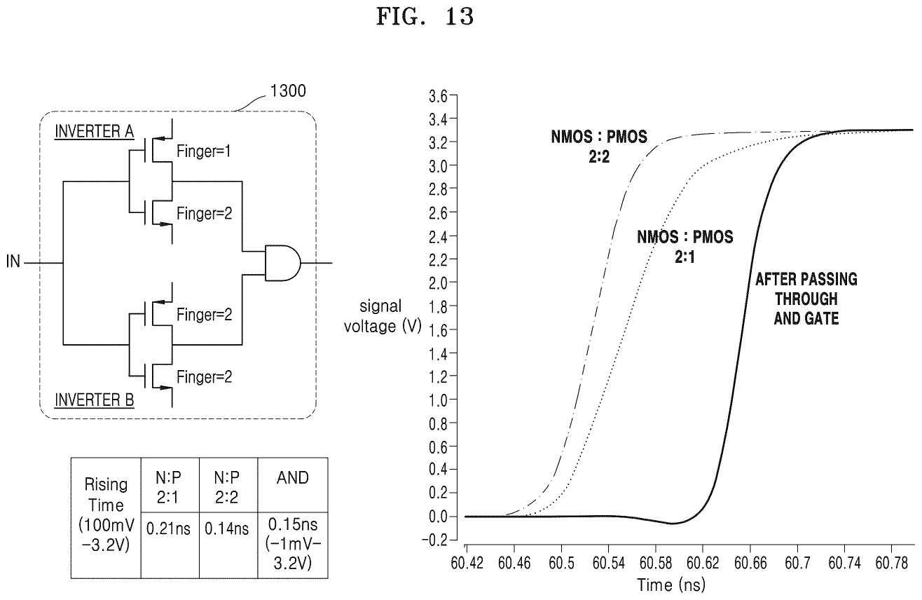

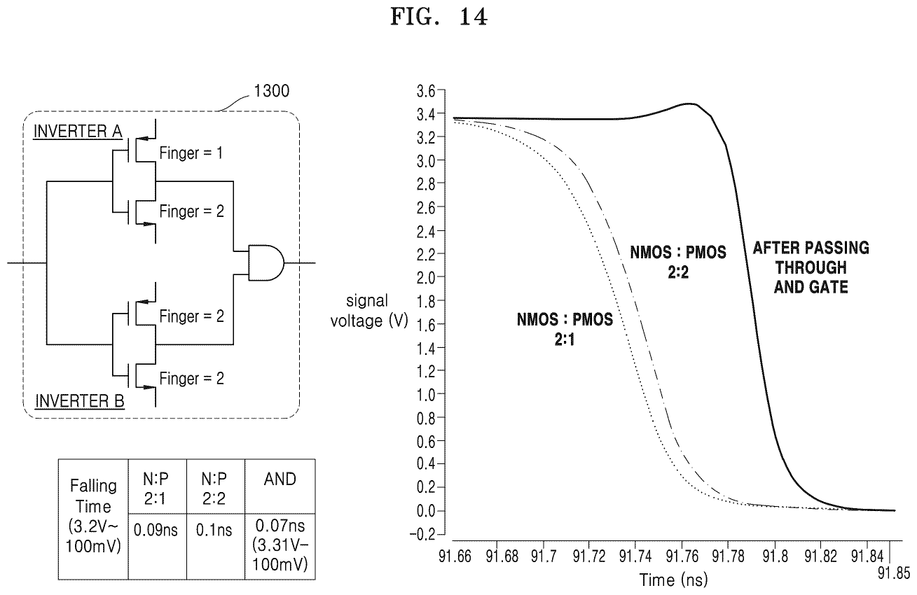

FIGS. 13 and 14 are views illustrating how to output an input signal after increasing the rising rate and the falling rate of the input signal using two inverters of an inverter group according to some example embodiments.

Referring to FIGS. 13 and 14, it may be seen that the rate of rising is high and the rate of falling is low by designing the sizes of a PMOS transistor and an NMOS transistor of an inverter A of an inverter group 1300 to be different from each other. However, in an inverter B of the inverter group 1300, the rate of falling is high and the rate of rising is low.

As described above, a dead time or latency occurring when the image sensing device 1100 processes a signal may be reduced (and may be reduced without excessive additional power consumption, thereby providing improved power consumption efficiency) by adding the latency reducing circuit unit 1050 to the image sensing device 1100, designing the sizes of the PMOS transistor and the NMOS transistor of an inverter of the inverter group 1300 of the latency reducing circuit unit 1050 to be different from each other for speeding up rising, and designing the sizes of the PMOS transistor and the NMOS transistor of the other inverter of the inverter group 1300 of the latency reducing circuit unit 1050 to be identical to each other for speeding up falling.

In addition, one or more programs including instructions for implementing some example embodiments described above may be recorded in a non-transitory computer-readable recording medium. Examples of the non-transitory computer-readable medium may include: magnetic media such as hard disks, floppy disks, and magnetic tapes; optical recording media such as CD-ROMs and DVDs; magneto-optical media such as floptical disks; and hardware such as ROMs, RAMs, and flash memories specifically configured to store program instructions and execute the program instructions. Examples of the program instructions may include not only a machine language code such as those generated by a compiler but also a high-level language code executable on a computer using an interpreter or the like.

As described herein, any devices, systems, units, blocks, circuits, controllers, processors, and/or portions thereof according to any of the example embodiments (including, for example, the LiDAR device 100, the laser light emitting unit 110, the image sensing device 120, the processor 130, the SPAD array 1010, the bias circuit unit 1020, the logic circuit unit 1030, the counter array 1040, the image sensing device 1100, the latency reducing circuit unit 1050, any portion thereof, or the like) may include, may be included in, and/or may be implemented by one or more instances of processing circuitry such as hardware including logic circuits; a hardware/software combination such as a processor executing software; or any combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid-state drive memory device, storing a program of instructions, and a processor (e.g., CPU) configured to execute the program of instructions to implement the functionality and/or methods performed by some or all of any devices, systems, units, blocks, circuits, controllers, processors, and/or portions thereof according to any of the example embodiments.

It should be understood that example embodiments described herein should be considered in a descriptive sense only and not for purposes of limitation. Descriptions of features or aspects within each example embodiment should typically be considered as available for other similar features or aspects in other example embodiments. While some example embodiments have been described with reference to the figures, it will be understood by those of ordinary skill in the art that various changes in form and details may be made therein without departing from the spirit and scope as defined by the following claims.

What is claimed is:

1. An image sensing device, comprising:
a single-photon avalanche diode (SPAD) array comprising an m×n array of SPAD pixels, m and n each independently being a natural number;
a signal transmission unit including m row lines connected in units of SPAD pixels of a same row of the SPAD array and n column lines connected in units of SPAD pixels of a same column of the SPAD array;
a bias circuit unit configured to
output a row bias signal corresponding to a row photon signal transmitted through a row line of the signal transmission unit, and
output a column bias signal corresponding to a column photon signal transmitted through a column line of the signal transmission unit;
a logic circuit unit configured to identify, based on the row bias signal and the column bias signal, a SPAD pixel of the SPAD array that has detected a photon; and
a counter array configured to perform photon counting with respect to a counter that corresponds to the identified SPAD pixel among an m×n array of counters corresponding to the m×n array of the SPAD array.

2. The image sensing device of claim 1, wherein the signal transmission unit is configured to provide the bias circuit unit with
the row photon signal such that the row photon signal has a current intensity corresponding to a number of SPAD pixels that have detected photons among SPAD pixels connected to a same row line, and
the column photon signal such that the column photon signal has a current intensity corresponding to a number of SPAD pixels that have detected photons among SPAD pixels connected to a same column line.

3. The image sensing device of claim 1, wherein the bias circuit unit comprises
first current mirror circuits at separate, respective ends of the m row lines, and
second current mirror circuits at separate, respective ends of the n column lines.

4. The image sensing device of claim 1, wherein
the logic circuit unit comprises an m×n array of logic gates corresponding to the m×n array of the SPAD array, and
each of the logic gates comprises:
a first input terminal connected to one of the m row lines; and
a second input terminal connected to one of the n column lines.

5. The image sensing device of claim 4, wherein the logic circuit unit is further configured to identify, as the SPAD pixel that has detected the photon, a SPAD pixel corresponding to a logic gate to which the row bias signal is input through the first input terminal of the logic gate and to which the column bias signal is input through the second input terminal of the logic gate among the logic gates.

6. The image sensing device of claim 4, wherein each of the logic gates comprises a NOR gate circuit comprising the first input terminal and the second input terminal.

7. The image sensing device of claim 5, wherein the counter array is further configured to perform the photon counting with respect to the counter corresponding to the logic gate to which the row bias signal is input through the first input terminal of the logic gate and to which the column bias signal is input through the second input terminal of the logic gate among the logic gates.

8. The image sensing device of claim 1, wherein
the logic circuit unit comprises logic gates connected to the SPAD pixels in a one-to-one manner, and
the counter array comprises counters connected to the logic gates in a one-to-one manner.

9. The image sensing device of claim 1, further comprising a latency reducing circuit unit configured to
receive a first row bias signal as an input to a first row inverter group,
provide an output of the first row inverter group to a first input terminal of a first logic gate in the logic circuit unit,
receive a first column bias signal as an input to a first column inverter group, and
provide an output of the first column inverter group to a second input terminal of the first logic gate in the logic circuit unit.

10. The image sensing device of claim 9, wherein
the first row inverter group comprises a first inverter and a second inverter and a first AND gate,
the first inverter and the second inverter and the first AND gate are configured to receive the first row bias signal, perform an AND operation on inverted signals of the first row bias signal, and output a result of the AND operation to the first input terminal of the first logic gate,
a strength of a p-channel metal-oxide-semiconductor (PMOS) transistor in the first inverter is greater than a strength of an n-channel metal-oxide-semiconductor (NMOS) transistor in the first inverter, and
a strength of a PMOS transistor in the second inverter is identical to a strength of an NMOS transistor provided in the second inverter.

11. The image sensing device of claim 9, wherein
the first column inverter group comprises a third inverter and a fourth inverter and a second AND gate,
the third inverter and the fourth inverter and the second AND gate are configured to receive the first column bias signal, perform an AND operation on inverted signals of the first column bias signal, and output a result of the AND operation to the second input terminal of the first logic gate, and
a strength of a PMOS transistor in the third inverter is greater than a strength of an NMOS transistor in the third inverter, and a strength of a PMOS transistor in the fourth inverter is identical to a strength of an NMOS transistor in the fourth inverter.

12. A light detection and ranging (LiDAR) device comprising:
the image sensing device of claim 1; and
a processor configured to generate, based on photon counting data received from the image sensing device, a digital image.

13. A method, comprising:
transmitting, from a bias circuit unit,
a row bias signal corresponding to a row photon signal transmitted through a row line connected to a single-photon avalanche diode (SPAD) pixel of a SPAD array, and
a column bias signal corresponding to a column photon signal transmitted through a column line connected to the SPAD pixel;
identifying, at a logic circuit unit, based on the row bias signal and the column bias signal, that the SPAD pixel has detected a photon; and
performing photon counting with respect to a counter that corresponds to the SPAD pixel.

14. The method of claim 13, wherein
the row photon signal has a current intensity corresponding to a number of SPAD pixels that have detected photons among SPAD pixels connected to a same row line, and
the column photon signal has a current intensity corresponding to a number of SPAD pixels that have detected photons among SPAD pixels connected to a same column line.

15. The method of claim 13, wherein
the logic circuit unit comprises a logic gate corresponding to the SPAD pixel, and
the logic gate includes
a first input terminal connected to the row line, and
a second input terminal connected to the column line.

16. The method of claim 15, further comprising:
identifying, the SPAD pixel as having detecting the photon based on both
the row bias signal being input through the first input terminal of the logic gate, and
the column bias signal being input through the second input terminal of the logic gate.

17. The method of claim 15, wherein the logic gate comprises a NOR gate circuit comprising the first input terminal and the second input terminal.

18. The method of claim 13, further comprising:
receiving the row bias signal as an input to a first row inverter group,
providing an output of the first row inverter group to a first input terminal of a logic gate,
receiving the column bias signal as an input to a first column inverter group, and
providing an output of the first column inverter group to a second input terminal of the logic gate.

19. The method of claim 18, wherein
the first row inverter group comprises a first inverter and a second inverter and a first AND gate, where a strength of a p-channel metal-oxide-semiconductor (PMOS) transistor in the first inverter is greater than a strength of an n-channel metal-oxide-semiconductor (NMOS) transistor in the first inverter, and a strength of a PMOS transistor in the second inverter is identical to a strength of an NMOS transistor provided in the second inverter,
the method includes inverting the row bias signal at the first inverter and the second inverter, performing an AND operation on inverted signals of the row bias signal at the first AND gate, and outputting a result of the AND operation to the first input terminal of the logic gate,
the first column inverter group comprises a third inverter and a fourth inverter and a second AND gate, where a strength of a PMOS transistor in the third inverter is greater than a strength of an NMOS transistor in the third inverter, and a strength of a PMOS transistor in the fourth inverter is identical to a strength of an NMOS transistor in the fourth inverter, and
the method includes inverting the column bias signal at the third inverter and the fourth inverter, performing an AND operation on inverted signals of the column bias signal at the second AND gate, and outputting a result of the AND operation to the second input terminal of the logic gate.

20. The method of claim 13, further comprising:
generating a digital image, based on the photon counting.
